(19) United States
(12) Patent Application Publication
(10) Pub. No.: US 2021/0078131 A1
(43) Pub. Date: Mar. 18, 2021

(54) HOLDING PLATE AND POLISHING METHOD OF SUBSTRATE

(71) Applicants: KABUSHIKI KAISHA TOSHIBA, Tokyo (JP); TOSHIBA ELECTRONICS DEVICES & STORAGE CORPORATION, Tokyo (JP)

(72) Inventors: Chisato FURUKAWA, Komatsu Ishihawa (JP); Takeshi Shibata, Nonoichi Ishikawa (JP)

(21) Appl. No.: 16/803,058

(22) Filed: Feb. 27, 2020

(30) Foreign Application Priority Data
Sep. 13, 2019 (JP) 2019-166908

(51) Int. Cl. B24B 41/06; H01L 21/67; H01L 21/683; H01L 21/304; B24B 7/22; B24B 7/04

(52) U.S. Cl. CPC B24B 41/06; H01L 21/67092; H01L 21/6836; H01L 2221/68327; B24B 7/228; B24B 7/04; H01L 21/304

(57) ABSTRACT

According to one embodiment, a substrate holding plate includes an inorganic material layer that has through holes and pores therein. The inorganic material layer has a first surface to which a flat surface of a substrate can be adhered for subsequent processing, such as polishing or the like. The pores of the inorganic material layer have an average diameter that is smaller than an average diameter of the through holes of the inorganic material layer.

### CROSS-REFERENCE TO RELATED APPLICATION

This application is based upon and claims the benefit of priority from Japanese Patent Application No. 2019-166908, filed Sep. 13, 2019, the entire contents of which are incorporated herein by reference.

### FIELD

Embodiments described herein relate generally to a holding plate and a polishing method of a substrate.

### BACKGROUND

As electronic devices are becoming more compact and thinner, the demand for means of thinning semiconductor chips is increasing. For example, in some cases, a 3-inch silicon wafer may be required to have a thickness of only 50 μm.

When a large-diameter wafer is thinned to 50 μm using a polisher after other wafer processing steps, the wafer is typically adhered to another component, such as a holding plate, for polishing so as to prevent the thinned wafer from being cracked or chipped.

In such case, the wafer (e.g., a semiconductor wafer) needs to be reliably adhered to the holding plate, but then the polished wafer needs to be detached from the holding in a manner that does not cause the wafer to crack or chip.

### DESCRIPTION OF THE DRAWINGS

FIG. 1A is a schematic cross-sectional view of a holding plate according to a first embodiment with a substrate adhered to the holding plate.

FIG. 1B is a schematic perspective view of a holding plate and an adhered substrate.

FIG. 2 is a flowchart fora polishing method of a substrate according to an embodiment.

FIG. 3A is a schematic cross-sectional view of the holding plate and the substrate illustrating aspects related to a polishing step.

FIG. 3B is a schematic perspective view of a holding plate and substrate after a polishing step.

FIG. 4A is a schematic cross-sectional view of a holding plate and substrate illustrating aspects related to a detachment step.

FIG. 4B is a schematic perspective view of a holding plate and substrate during a detachment step.

FIG. 5A is a schematic cross-sectional view of a holding plate and substrate after detachment.

FIG. 5B is a schematic perspective view of a holding plate and substrate after detachment.

FIG. 6 is a schematic cross-sectional view of a holding plate according to a second embodiment.

### DETAILED DESCRIPTION

Certain example embodiments provide a holding plate that facilitates the adhesion of a substrate to the holding plate for polishing and the detachment of the substrate from the holding plate after polishing.

In general, according to one embodiment, a substrate holding plate includes an inorganic material layer that has through holes and pores therein. The inorganic material layer has a first surface to which a flat surface of a substrate can be adhered for subsequent processing, such as polishing or the like. The pores in the inorganic material layer have an average diameter that is smaller than an average diameter of the through holes in the inorganic material layer.

In this context, a substrate adhered to a holding plate may be referred to as a processing target, a processing workpiece, or a polishing target (when subsequent substrate processing will include a polishing-type process). A substrate processing method may include a processing step or processing steps (or stages) associated with an overall manufacturing method of device, such as semiconductor device manufacturing, in which either the substrate itself or a sub-portion of the substrate is considered a final product.

Hereinafter, various example embodiments of the present disclosure will be described with reference to the drawings.

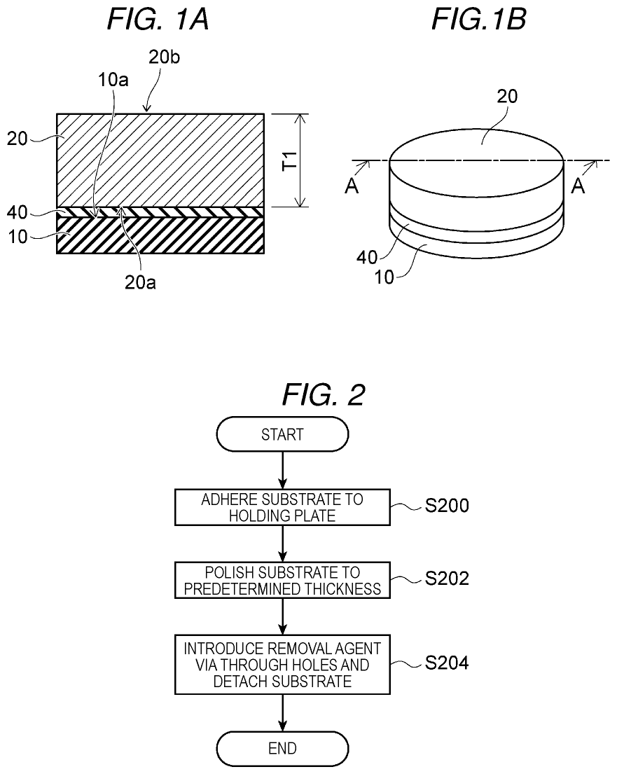

FIG. 1A is a schematic cross-sectional view of a holding plate according to a first embodiment with a substrate adhered to the holding plate. The cross-section is taken along line A-A in FIG. 1B. FIG. 1B is a schematic perspective view of the holding plate and the substrate depicted in FIG. 1A.

As illustrated in FIG. 1A, a substrate 20 is adhered to a holding plate 10 using an adhesive 40, for example. The substrate is made of a material such as sapphire, diamond, silicon carbide (SiC), gallium nitride (GaN), boron nitride (BN), silicon (Si), or germanium (Ge). In this example, a semiconductor crystal layer is formed on the substrate 20. In the case of silicon, the substrate 20 has, for example, a wafer size (diameter) of 2 inches to 4 inches, and a thickness T1 of 150 μm to 300 μm.

The holding plate 10 includes or comprises a layer of porous inorganic material having both through holes and pores. A first surface 10a of the porous inorganic material is adhered to a substantially flat surface 20a of the substrate 20. The surface 20a is a surface of the substrate 20 on which, for example, a circuit element has previously been formed or otherwise disposed. The pores in the porous inorganic material have an average diameter smaller than an average diameter of the through holes in the porous inorganic material. The porous inorganic material layer may comprise, for example, one of SiO₂ (silica; silicon oxide), alumina (Al₂O₃; aluminum oxide), SiC, and titanium nitride (TiN). The porous inorganic material layer may be an integral material or may comprise pulverized particles such as those obtained by pulverizing an integral material and the segregating the resulting particles by size of the like. In some examples, the porous inorganic material layer may be, or otherwise comprise, a sintered body of pulverized particles.

In this example, the porous inorganic material layer comprises a framework of material. The framework is a three-dimensional continuous mesh structure. In this context, the “through holes” are formed as voids in the framework and provide flow paths in the layer from outer layer surface to outer layer surface. The “pores” in this context are of a smaller dimension than the through holes. These pores may extend inward from a surface of the framework of material in the layer, but need not necessarily provide a flow path through the layer.

The holding plate 10 may have a disk shape, as illustrated in FIG. 1B, because the holding plate 10 is to be mounted on a polishing plate of a rotary polishing turntable or the like.

Table 1 illustrates average diameters (μm) of the through holes and average diameters (nm) of the pores for different diameters of the holding plate. The holding plate 10 in this instance is comprised of silica.

TABLE 1

| Diameter [mm] of | Average diameter | Average diameter |
|---|---|---|
| holding plate | [μm] of through holes | [nm] of pores |
| ϕ20 to ϕ30 | 0.5, 1, 2, 5, 10, 20 | 10, 15, 20, 30, 50 |
| ϕ30 to ϕ60 | 0.8, 1, 2, 5 | 10, 15, 20, 30 |
| ϕ60 to ϕ100 | 1, 2, 3, 5 | 15, 20, 30 |
| ϕ100 to ϕ120 | 1, 2, 3, 5 | 15, 20, 30 |

When the disk-shaped holding plate has a diameter of 20 mm to 120 mm, the through holes may have an average diameter in a range of about 0.5 μm to 20 μm, and the pores may have an average diameter in a range of about 10 nm to 50 nm. In this case, the average diameter of the pores is, for example, 10% or less of the average diameter of the through holes.

When the average diameter of the through holes is 2 μm and the average diameter of the pores is 20 nm, a specific surface area is 250 m²/g, a pore volume is 1.0 cm³/g, and a porosity when filled is approximately 93%. Since the framework structure of the porous inorganic material layer extends three-dimensionally, it can be difficult to measure or estimate the diameters of the through holes and the pores. In Table 1, the diameters have been calculated from a scanning electron microscope (SEM) sectional image and averaged. Table 1 indicates that, in general, the porosity of the silica material is high.

FIG. 2 is a flowchart of a substrate polishing method according to this embodiment.

At aspect S200, the substrate is adhered to the holding plater. That is, as illustrated in FIGS. 1A and 1B, the first surface 10a of the porous inorganic material layer of the holding plate 10 and the flat surface 20a of the substrate 20 are adhered with an adhesive 40 in such a manner that the first surface 10a is substantially parallel to and facing the flat surface 20a. The adhesive 40 may be an organic material (such as acrylic) having favorable flatness after applied. The flat surface 20a is a surface of a semiconductor epitaxial crystal layer where circuit elements (e.g., transistors) or the like are disposed. Since the average diameter of the through holes is as indicated in Table 1, the adhesive 40 does not substantially enter the porous inorganic material layer because the diameter of the through holes is relatively small (e.g., 20 microns or less). However, the adhesive can still provide adhesive strength enough to hold the substrate 20.

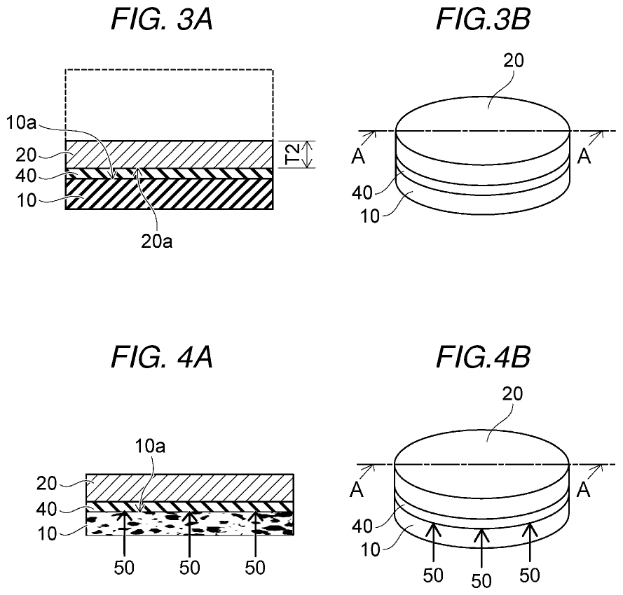

In aspect S202, the substrate 20 is polished to a predetermined thickness. FIG. 3A is a schematic cross-sectional view of the holding plate 10 and the substrate 20, illustrating aspects of a polishing step. FIG. 3B is a schematic perspective view of the holding plate and the substrate after polishing.

The substrate 20 has a rear surface 20b (see FIG. 1A) opposite to the flat surface 20a. This rear surface 20b is the surface polished in a polisher or the like. Typically, the rear surface 20b of the substrate 20 is rotationally polished in a polisher and consequently the substrate 20 is thinned to some predetermined thickness T2 from an initial thickness T1, as has been illustrated in FIG. 3A. The predetermined thickness T2 can be as small as 50 μm to 100 μm, for example.

In aspect S204, a removal agent 50 (see FIG. 4A & FIG. 4B) is introduced and the substrate 20 is detached from the holder 10. FIG. 4A is a schematic cross-sectional view of the holding plate 10 and the substrate 20, illustrating aspects of a detachment step. FIG. 4B is a schematic perspective view of the holding plate 10 and the substrate 20 during the detachment step. In FIG. 4B, the holding plate 10 is depicted as comprising the porous inorganic material with through holes (through which removal agent 50 is depicted as flowing through in a general manner via the arrows) and also pores of smaller dimension than the through holes.

FIG. 5A is a schematic cross-sectional view of the holding plate 10 and the substrate 20 after being detached. FIG. 5B is a schematic perspective view of the holding plate 10 and the substrate 20.

A removal agent 50 comprising an organic substance in a liquid phase or a gas phase is passed through the through holes of the inorganic material layer of the substrate 20. The removal agent 50 reacts with the adhesive 40 to permit the polished substrate 20 to be detached from the holding plate 10. In general, the through holes in the porous inorganic material layer are positionally uniformly dispersed within the porous inorganic material layer such that through holes will be present all over the corresponding planar area of the wafer (e.g., substrate 20). Consequently, the removal agent 50 is supplied to the whole wafer (substrate 20) in a substantially uniform manner, and as illustrated in FIGS. 5A and 5B, the adhesive 40 can be removed from substantially the whole wafer substantially uniformly. It is noted that examples of the removal agent 50 include solvents such as acetone, toluene, and benzene, which are capable of dissolving the adhesive 40 or otherwise causing the adhesive 40 to lose its adhesiveness.

In general, when the porous inorganic material layer is hydrophobic, the aqueous etchants containing acidic (or alkaline) components, will not pass through the through holes in a wet etching process or the like. This is preferable because such an etchant (for example, as might be used in conjunction with chemical mechanical polishing processes) will be prevented from unintentionally affecting the adhesive 40 (and/or surface 20a) during processing of the substrate 20. That is, the holding plate 10 provides acid resistance and alkali resistance to protect the surface 20a of the substrate 20 while maintaining adhesive strength between the substrate 20 and the holding plate 10.

A holding plate of a comparative example will now be described.

The holding plate in the comparative example (hereinafter referred to as “support plate”) is made of a material such as glass and ceramic. The support plate has a plurality of through holes vertically extending through the support plate. A wafer and the support plate are secured to each other with an adhesive. With a tape interposed between the wafer and the support plate, vacuum adsorption is performed via the openings of the through holes in a surface of the support plate where the wafer is not secured with the adhesive, and the wafer is then ground/polished in this state.

In the comparative example, removal of the adhesive is irregular for those regions close to the through holes and those regions away from the through holes. For example, the adhesive may remain partly unremoved after separation of the support plate. When the support plate made of glass, a removal process particular to glass is required. In contrast, according to an embodiment of the present disclosure, the substrate 20 is prevented from being cracked and chipped when detached from the holding plate 10 even though the adhesive strength between the substrate 20 and the holding plate 10 is maintained during all processing prior to removal processing. Removal processing in this context, refers to holding plate 10 separation from substrate 20 by a process including introduction of removal agent 50 via, for example, the backside of holding plate 10).

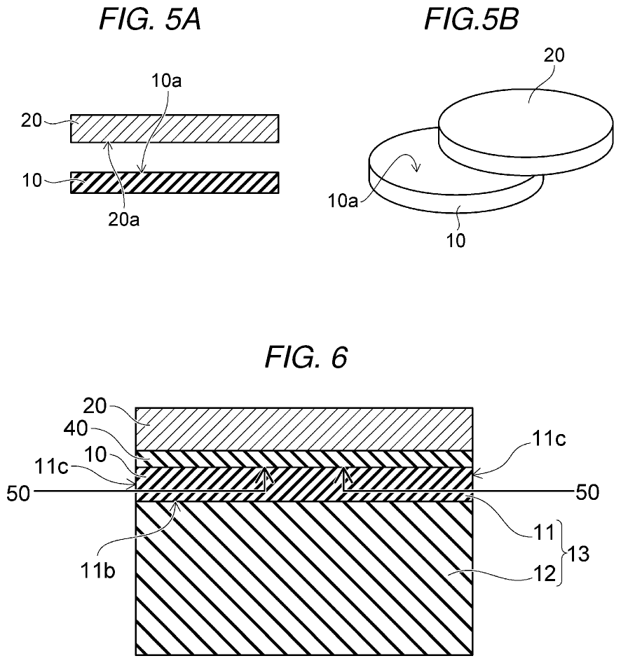

FIG. 6 is a schematic cross-sectional view of a holding plate according to a second embodiment.

A holding plate 13 includes a porous inorganic material layer 11 and a reinforcement layer 12 adjacent to a second surface 11b of the porous inorganic material layer 11. Through holes are partly exposed at side surfaces 11c of the porous inorganic material layer 11. When the porous inorganic material layer 11 cannot be made sufficiently thick for substrate processing purposes, for example, the porous inorganic material layer 11 alone cannot provide sufficient strength to withstand the polishing process the reinforcement layer 12 can be incorporated. If the reinforcement layer 12 is transparent to light, the progress of detachment of the substrate can be monitored. For example, a quartz substrate, a doubled-sided mirror-processed SiC single-crystal substrate, and a sapphire substrate, may be used for the reinforcement layer 12. In other examples, the reinforcement layer 12 need not be transparent.

According to the second embodiment, a solid inorganic material as the reinforcement layer 12 is adhered to or otherwise integrally formed with the porous inorganic material layer 11 so as to maintain strength as the holding plate. Since side surfaces 11c of the porous inorganic material layer 11 are exposed, this allows removal agent 50 to pass through the through holes and reach the adhesive 40 for detaching the substrate 20. In this context, the material of the porous inorganic material layer 11 can be same porous inorganic material described in conjunction with holding plate 10 of the first embodiment.

Above-described example embodiments of the present disclosure provide a holding plate that facilitates adhesion of a substrate to the holding plate for processing (e.g., polishing) while also providing an improved means for detachment of the substrate from the holding plate at the end of processing. Thus, even when a large-diameter semiconductor wafer is to be thinned or the like, the wafer can be prevented from being cracked and chipped. This facilitates the reduction in thickness and size of electronic devices.

While certain embodiments have been described, these embodiments have been presented by way of example only, and are not intended to limit the scope of the present disclosure. Indeed, the novel embodiments described herein may be embodied in a variety of other forms; furthermore, various omissions, substitutions and changes in the form of the embodiments described herein may be made without departing from the spirit of the present disclosure. The accompanying claims and their equivalents are intended to cover such forms or modifications as would fall within the scope and spirit of the present disclosure.

What is claimed is:

1. A substrate holding plate, comprising an inorganic material layer having through holes and pores therein, the inorganic material layer having a first surface to which a flat surface of a substrate can be adhered, wherein
the pores of the inorganic material layer have an average diameter smaller than an average diameter of the through holes of the inorganic material layer.

2. The substrate holding plate according to claim 1, wherein the average diameter of the through holes is within a range of 0.5 μm to 20 μm.

3. The substrate holding plate according to claim 1, wherein the inorganic material layer is hydrophobic.

4. The substrate holding plate according to claim 1, wherein the inorganic material layer comprises one of silicon oxide, alumina, silicon carbide, or titanium nitride.

5. The substrate holding plate according to claim 1, wherein the inorganic material layer consists of one material selected from a group consisting of silicon oxide, alumina, silicon carbide, or titanium nitride.

6. The substrate holding plate according to claim 1, wherein the inorganic material layer is silicon oxide.

7. The substrate holding plate according to claim 1, wherein the inorganic material layer comprises a sintered material.

8. The substrate holding plate according to claim 1, wherein the inorganic material layer comprises sintered particles.

9. The substrate holding plate according to claim 1, further comprising:
a reinforcement layer contacting a second surface of the inorganic material layer opposite the first surface.

10. The substrate holding plate according to claim 9, wherein the inorganic material layer has side surfaces at which through holes are exposed.

11. The substrate holding plate according to claim 9, wherein the reinforcement layer is a transparent material.

12. The substrate holding plate according to claim 9, wherein the reinforcement layer is quartz, single-crystal silicon carbide, or sapphire.

13. A polishing target, comprising:
a holding plate including an inorganic material layer having through holes and pores therein, the inorganic material layer having a first surface; and
a substrate adhered to the first surface with an adhesive material disposed between the first surface and the substrate, wherein
the pores of the inorganic material layer have an average diameter smaller than an average diameter of the through holes of the inorganic material layer.

14. The polishing target according to claim 13, wherein the adhesive dissolves in organic solvent.

15. The polishing target according to claim 13, wherein the holding plate further includes:
a reinforcement layer contacting a second surface of the inorganic material layer opposite the first surface.

16. The polishing target according to according to claim 15, wherein the reinforcement layer is transparent material.

17. The polishing target according to claim 13, wherein the inorganic material layer comprises silicon oxide and the substrate is a semiconductor wafer.

18. A substrate processing method comprising:
adhering a flat surface of a substrate to a holding plate with an adhesive, wherein the holding plate comprises an inorganic material layer having through holes and pores therein, the inorganic material layer having a first surface to which the flat surface of the substrate is adhered;
polishing an opposite surface of the substrate that is opposite to the flat surface and thinning the substrate to a predetermined thickness in the polishing; and
supplying a removal agent comprising an organic solvent to an exposed surface of the holding plate after the polishing to weaken the adhesive strength of the adhesive adhering the flat surface of the substrate to the holding plate; and
detaching the substrate from the holding plate after supplying the removal agent, wherein
the pores of the inorganic material layer have an average diameter smaller than an average diameter of the through holes of the inorganic material layer.

19. The substrate processing method according to claim 18, wherein the holding plate further comprises a reinforcement layer.

20. The substrate processing method according to claim 18, wherein the substrate comprises at least one of sapphire, diamond, silicon carbide, gallium nitride, boron nitride, silicon, and germanium.
